(19) United States
(12) Patent Application Publication
(10) Pub. No.: US 2009/0151637 A1
(43) Pub. Date: Jun. 18, 2009

(54) MICROWAVE-EXCITED PLASMA SOURCE USING RIDGED WAVE-GUIDE LINE-TYPE MICROWAVE PLASMA REACTOR

(75) Inventors: CHIH-CHEN CHANG, Taipei County (TW); TUNG-CHUAN WU, Hsinchu City (TW); FU-CHING TUNG, Hsinchu City (TW); MUH-WANG LIANG, Miaoli County (TW); CHING-HUEI WU, Hsinchu City (TW); CHAN-HSING LO, Hsinchu County (TW); TEAN-MU SHEN, Hsinchu City (TW); JUNG-CHEN CHIEN, Hsinchu County (TW); JUNG-CHEN HO, Hsinchu City (TW)

Correspondence Address: WPAT, PC, 7225 BEVERLY ST., ANNANDALE, VA, 22003, US

(73) Assignee: Industrial Technology Research Institute, Hsinchu (TW)

(21) Appl. No.: 12/129,009

(22) Filed: May 29, 2008

(30) Foreign Application Priority Data
Dec. 13, 2007 (TW) 096147689

(51) Int. Cl. C23C 16/00; H01L 21/3065

(52) U.S. Cl. 118/723 MW; 156/345.41

(57) ABSTRACT

A microwave-excited plasma source using a ridged wave-guide line-type microwave plasma reactor is disclosed. The microwave-excited plasma source comprises a reaction chamber, a ridged wave-guide and a separation plate. The ridged wave-guide is disposed on the reaction chamber, and comprises a frame portion, a ridge portion and a line-shaped slot. The line-shaped slot is disposed on a first side of the frame portion, and the ridge portion facing the line-shaped slot is disposed on a second side of the frame portion. The separation plate is disposed on the line-shaped slot. Moreover, the ridged wave-guide is suitable for concentrating microwave power, which is transmitted to the reaction chamber through the line-shaped slot in order to excite plasma.

### BACKGROUND OF THE INVENTION

1. Field of the Invention

The present invention generally relates to a microwave-excited plasma source and, more particularly, to a microwave-excited plasma source using a ridged wave-guide line-type microwave plasma reactor.

2. Description of the Prior Art

In semiconductor processing, an integrated circuit (IC) is manufactured using repeated steps such as thin film deposition, photolithography and etching. The film quality determines the reliability of the products manufactured. Generally, a thin film is formed by plasma formed of reactive gaseous ions to deposit on the substrate. Moreover, plasma is generated by applying a high voltage across two electrodes or using microwave excitation.

Nowadays, humans are using up the fossil fuels and therefore the solar energy has been considered as one of the alternative energies. Solar cells can be made of plasma-assisted silicon nitride films. To date, the manufacturing cost of the solar cell is still very high and the throughput is low. This makes the solar cell uncompetitive in the market.

FIG. 1A and FIG. 1B are side views of a conventional microwave-excited plasma source from different viewing angles. The microwave-excited plasma source 100 is disclosed in Germany Patent DE19812558A1. In FIG. 1A and FIG. 1B, the conventional microwave-excited plasma source 100 comprises a reaction chamber 110, a quartz tube 120 and a coaxial wave-guide 130. The coaxial wave-guide 130 is disposed inside the quartz tube 120. The quartz tube 120 is disposed inside the reaction chamber 110.

Therefore, when microwave 50 is applied to the coaxial wave-guide 130, the microwave 50 travels inside the coaxial wave-guide 130 and then leaks out of the surface of the coaxial wave-guide 130 to pass through the quartz tube 120 to excite plasma 60. The plasma 60 reaches the surface of the silicon substrate 140 to form a thin film. Then, processing steps such as thin film deposition, photolithography and etching are repeated so as to form solar cells or other IC's.

However, since the quartz tube 120 is surrounded by the plasma 60, which causes deposition on the quartz tube 120 and even etching on the quartz tube 120. This results in poor efficiency and poor plasma intensity of plasma 60 excited by microwave 50 so that the film quality on the silicon substrate 140 is degraded.

Therefore, the quartz tube 120 has to be renewed periodically to enhance the efficiency of plasma 60 excited by the microwave 50. However, the replacement of the quartz tube 120 is not very easy, which causes lower throughput of the microwave-excited plasma source 100. This increases the manufacturing cost of the solar cells.

Accordingly, since microwave 50 radially travels inside the coaxial wave-guide 130. The plasma 60 excited by the microwave 50 is disposed inside the reaction chamber 110. Then, thin film deposition is performed on the silicon substrate 140. If the size of the silicon substrate 140 is to be increased to enhance the throughput, the volume of the reaction chamber 110 has to be enlarged to raise the manufacturing cost.

In the conventional technique, film deposition is performed only on a single silicon substrate 140 with low throughput. Moreover, in the reaction chamber 110, plasma 60 is outside the film growth region of the silicon substrate 140, which causes power consumption. Even though the distance between the silicon substrate 140 and the coaxial wave-guide 130 can be reduced to improve the efficiency of plasma 60, for different locations of the silicon substrate 140, the plasma intensity will vary to cause non-uniformity of thin films on the silicon substrate 140 to degrade to solar cell quality.

### SUMMARY OF THE INVENTION

The present invention provides a microwave-excited plasma source using a ridged wave-guide line-type microwave plasma reactor so as to reduce the operation cost, enhance the throughput and improve the film quality.

Moreover, the present invention provides a microwave-excited plasma source, comprising a reaction chamber, a ridged wave-guide and a separation plate. The ridged wave-guide is disposed on the reaction chamber and comprises a frame portion, a line-shaped slot and a ridge portion. The line-shaped slot is disposed on a first side of the frame portion. The first side is adjacent to the reaction chamber. The ridge portion is disposed on a second side of the frame portion. The ridge portion faces the line-shaped slot. The separation plate is disposed on the line-shaped slot.

In one embodiment of the present invention, the reaction chamber comprises an opening. The ridged wave-guide is disposed above the opening and the line-shaped slot faces the opening.

In one embodiment of the present invention, the separation plate is formed of quartz glass and the ridged wave-guide is formed of metal.

In one embodiment of the present invention, the distance between the ridge portion and the line-shaped slot is within a range from 0 to ¼ of the wavelength of the microwave, and the width of the line-shaped slot is within a range from 0 to the width of the first side.

In one embodiment of the present invention, the first side is a first wide side, and the second side is a second wide side.

In one embodiment of the present invention, the ridged wave-guide is capable of concentrating microwave power, which is transmitted into the reaction chamber through the line-shaped slot in order to excite plasma.

In the microwave-excited plasma source of the present invention, the area of the separation plate exposed to plasma is smaller than that of the conventional quartz tube. There is less possibility for film deposition on the separation plate and less possibility for plasma etching on the separation plate. Therefore, the separation plate can be less frequently renewed to reduce the maintenance cost of the microwave-excited plasma source. Furthermore, the microwave power in the ridged wave-guide leaks into the reaction chamber through the separation plate so that the surface-wave plasma can be excited. The excited plasma is mostly used for thin-film deposition on the substrate to achieve better thin-film quality at a high growth rate. Furthermore, a carrier tape or a conveyor is also used to carry the substrate for continuous treatment.

### BRIEF DESCRIPTION OF THE DRAWINGS

The objects, spirits and advantages of the preferred embodiments of the present invention will be readily understood by the accompanying drawings and detailed descriptions, wherein:

FIG. 1A and FIG. 1B are side views of a conventional microwave-excited plasma source from different viewing angles;

FIG. 2A is a 3-D view of a part of a microwave-excited plasma source according to a first embodiment of the present invention;

FIG. 2B is a front view of a microwave-excited plasma source in FIG. 2A after being assembled;

FIG. 2C is a side view of a microwave-excited plasma source in FIG. 2A after being assembled; and

FIG. 2D is a schematic diagram showing microwave leaking out of a ridged wave-guide.

### DETAILED DESCRIPTION OF THE PREFERRED EMBODIMENT

The present invention can be exemplified by but not limited to the preferred embodiment as described hereinafter.

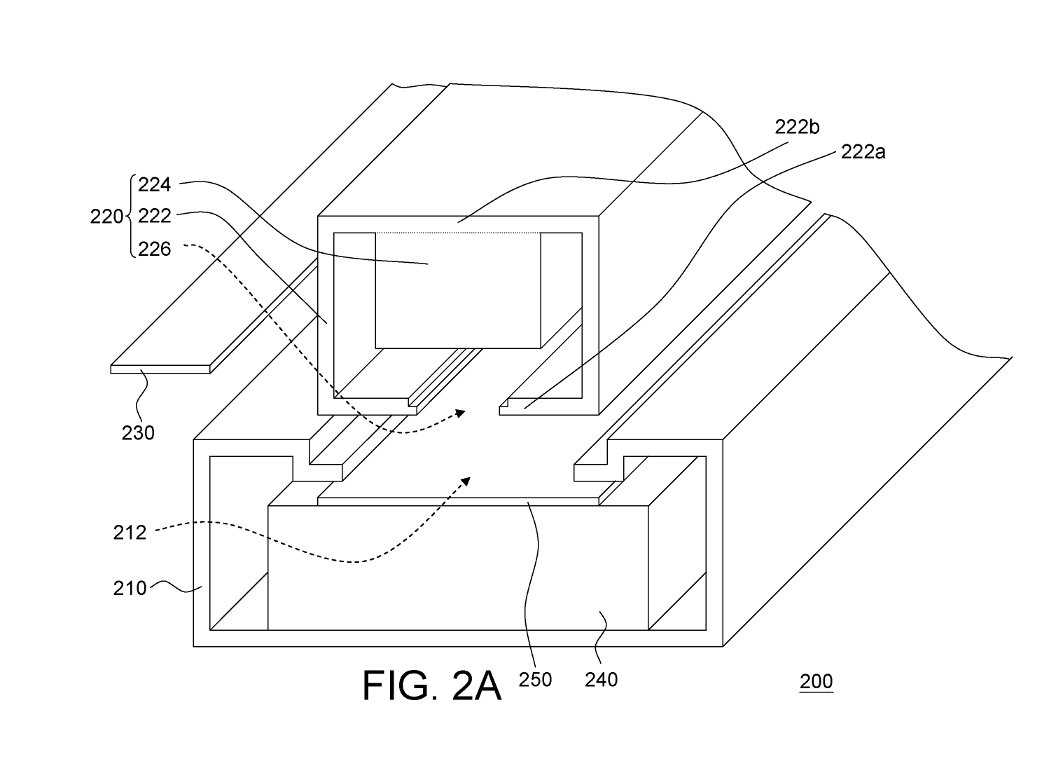

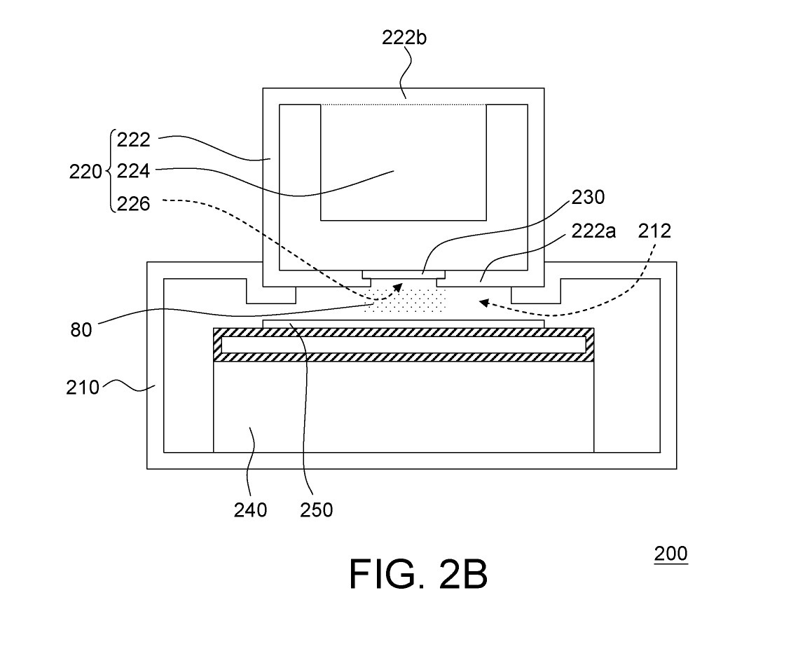

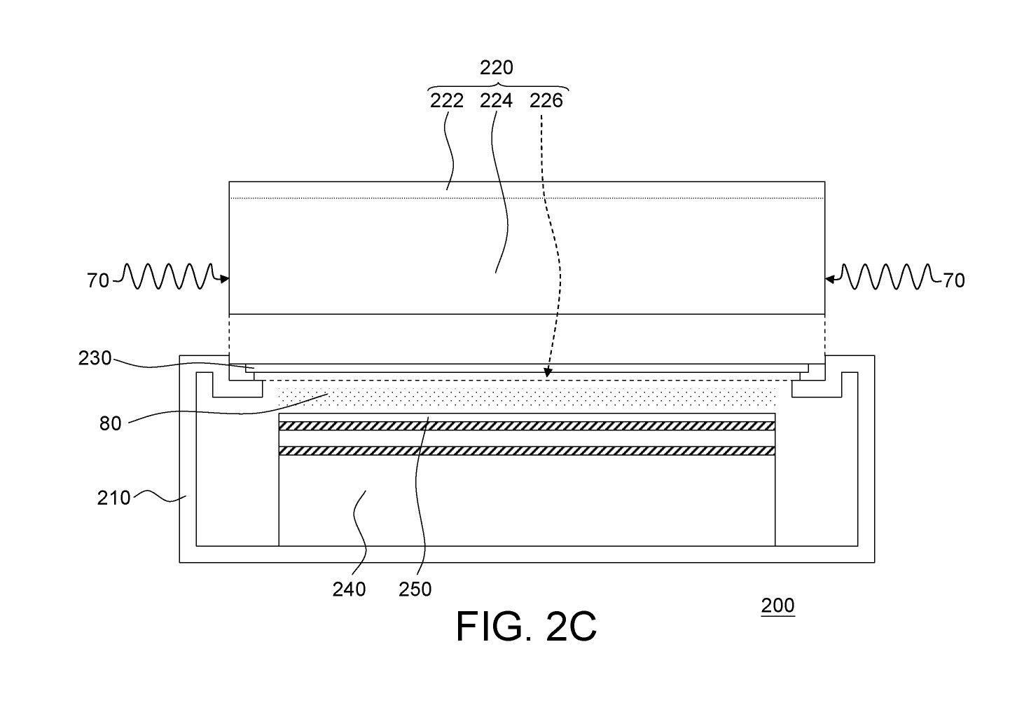

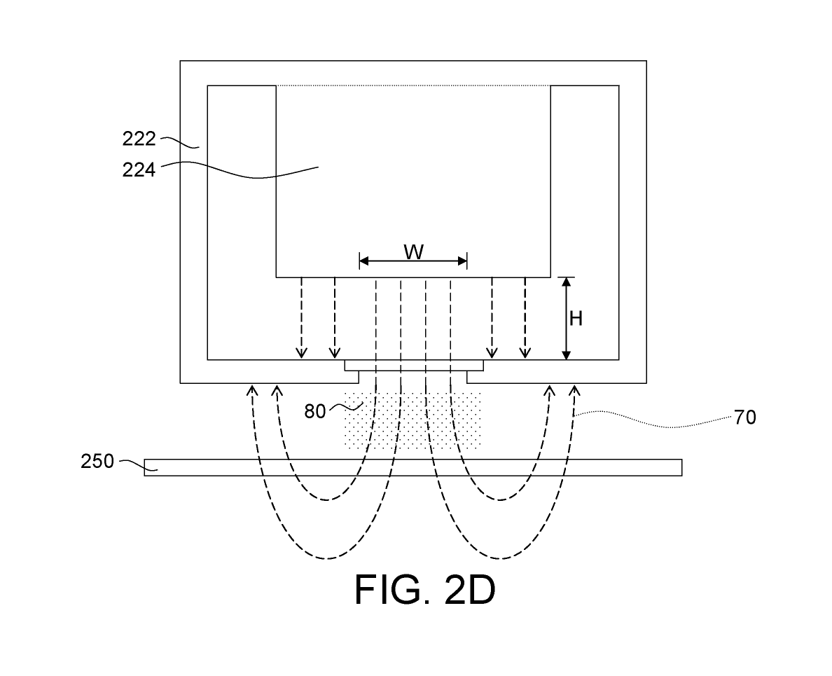

FIG. 2A is a 3-D view of a part of a microwave-excited plasma source according to a first embodiment of the present invention; FIG. 2B is a front view of a microwave-excited plasma source in FIG. 2A after being assembled; and FIG. 2C is a side view of a microwave-excited plasma source in FIG. 2A after being assembled. Please refer to FIG. 2A to FIG. 2C, wherein the microwave-excited plasma source 200 comprises a reaction chamber 210, a ridged wave-guide 220 and a separation plate 230. The ridged wave-guide 220 is disposed on the reaction chamber 210 and comprises a frame portion 222, a line-shaped slot 226 and a ridge portion 224. The line-shaped slot 226 is disposed on a first side 222a of the frame portion 222. The first side 222a is adjacent to the reaction chamber 210. The ridge portion 224 is disposed on a second side 222b of the frame portion 222. The ridge portion 224 faces the line-shaped slot 226. The separation plate 230 is disposed on the line-shaped slot 226.

Therefore, when microwave 70 is applied to the ridged wave-guide 220, the microwave 70 travels inside the ridged wave-guide 220. According to the microwave theory, the microwave 70 leaks out of the bottom edge of the ridge portion 224 of the ridged wave-guide 220 toward the reaction chamber 210 to excite plasma 80.

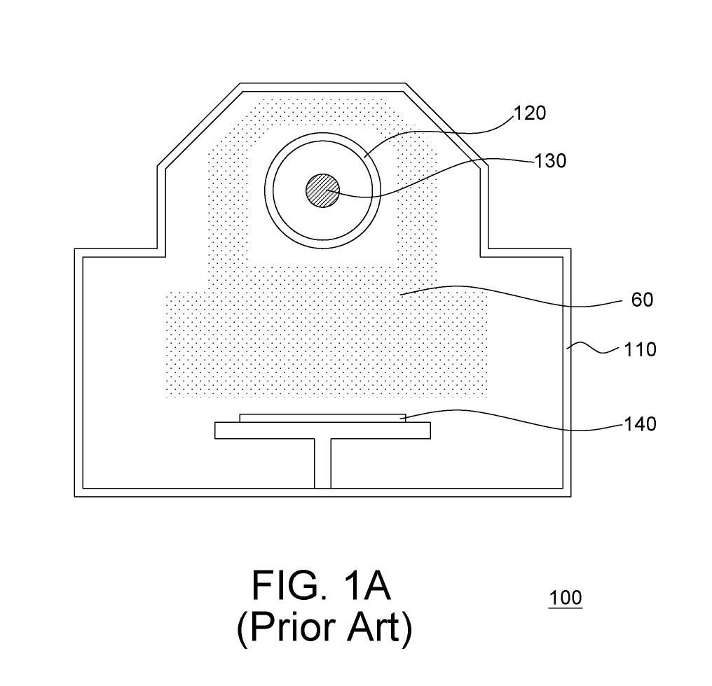

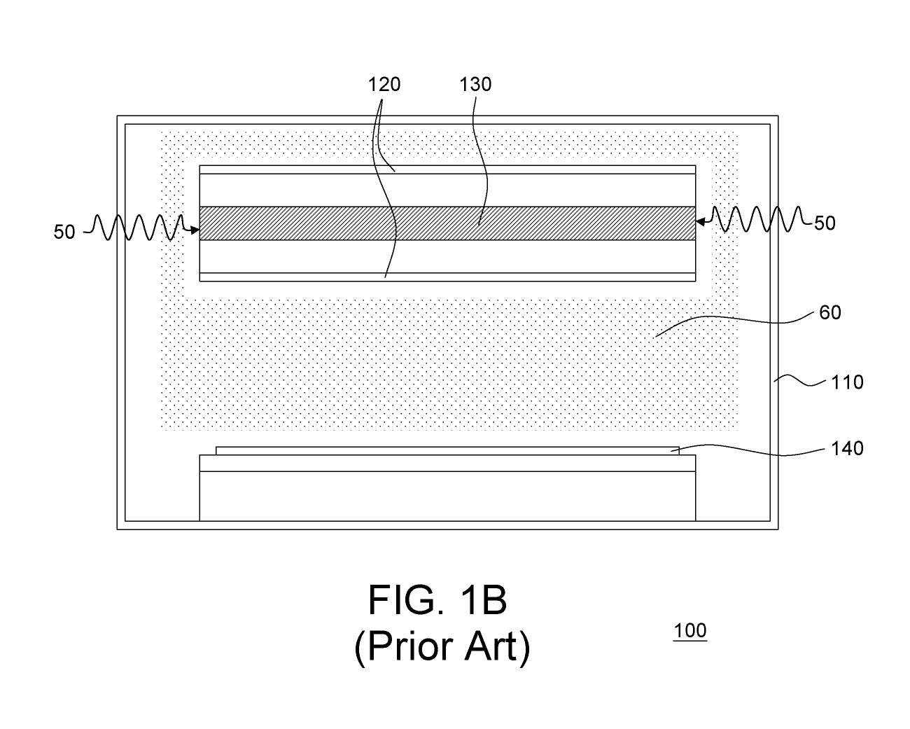

Since the area of the separation plate 230 exposed to plasma 80 is smaller than that of the conventional quartz tube 120 exposed to plasma 60 (as shown in FIG. 1A and FIG. 1B). There is less possibility for film deposition on the separation plate and less possibility for deformation of the separation plate 230 caused by plasma etching. Therefore, the separation plate 230 can be less frequently renewed so that the throughput of the microwave-excited plasma source 200 can be increased. In the present embodiment, the reaction chamber 210 comprises an opening 212. The ridged wave-guide 220 is disposed above the opening 212 and the line-shaped slot 222 faces the opening 212. Moreover, a base 240 can be disposed under the line-shaped slot 226 and a substrate 250 is disposed on the base 240 so that a film can be deposited using plasma 80 on the substrate 250.

There is an atmospheric pressure inside the ridged wave-guide 220. The pressure inside the reaction chamber 210 is lower. The separation plate 230 separates the ridged wave-guide 220 and the reaction chamber 210. Beneath the separation plate, reaction gases (not shown) are introduced into the reaction chamber 210 so that the reaction gases are excited by microwave to generate plasma 80 to deposit a thin film on the substrate 250.

It is noted that plasma 80 is used for film deposition on the substrate 250. However, the plasma 80 in the present invention is not limited thereto. For example, plasma can also be used to etch the substrate.

Furthermore, the microwave power leaks from the ridge portion of the ridged wave-guide through the separation plate. In other words, the excited plasma is mostly used for thin-film deposition on the substrate to achieve better film quality at a high growth rate. Furthermore, a carrier tape (or a conveyor) is also used to carry the substrate so that the throughput can be enhanced. Moreover, the substrate 250 can be a silicon-wafer substrate, a transparent glass substrate, a polymer substrate or the like. The separation plate 230 is implemented by using quartz glass which is sealed by an O-ring.

In FIG. 2A to FIG. 2C, the first side 222a whereon the line-shaped slot 226 is disposed and the second side 222b whereon the ridge portion 224 is disposed are both wide sides of the ridged wave-guide 220. In other words, the first side 222a is the first wide side and the second side 222b is the second wide side according to one embodiment of the present invention. Alternatively, the ridge portion 224 and the line-shaped slot 226 can also be disposed on the narrow sides of the ridged wave-guide 220.

The ridged wave-guide 220 is formed of metal such as aluminum, copper, stainless steel or the like. In the present embodiment, the cross-section of the line-shaped slot 226 is step-wise so that the separation plate 230 is disposed. However, the cross-section of the line-shaped slot 226 is not limited thereto in the present invention.

FIG. 2D is a schematic diagram showing the electric field of microwave leaking out of a ridged wave-guide. In FIG. 2D, microwave 70 in the ridged wave-guide leaks outward from the separation plate 230 and the electric field of the microwave 70 is perpendicular to the separation plate 230 so that the plasma is concentrated beneath the separation plate 230. The plasma 80 excited by microwave 70 reaches the surface of the substrate to form a thin film and to achieve better film quality at a high growth rate.

Furthermore, a carrier tape (not shown) is disposed on the base 240 to carry the substrate 250. By setting a proper speed of the carrier tape (or a conveyor), the line-shaped plasma 80 uniformly reaches the surface of the substrate 250 so as to form a thin film on the substrate 250. As a result, compared to conventional film deposition on a single substrate, in the present invention, multiple substrates can be disposed on the carrier tape to form thin films thereon. Therefore, the throughput can be enhanced.

Experimentally, plasma density and uniformity depend on wave leakage of the ridged wave-guide. In other words, microwave radiation is controlled by adjusting the position of the ridge portion 224 relative to the line-shaped slot. More particularly, the height H of the bottom edge of the ridge portion 224 relative to the line-shaped slot and the width W of the line-shaped slot are used to control the wave leakage of the ridged wave-guide so as to obtain high-density and uniform plasma 80. Generally, when the height H is smaller or the width W is larger, the wave leakage of the ridged wave-guide gets larger; on the contrary, when the height H is larger or the width W is smaller, the wave leakage of the ridged wave-guide gets smaller.

Moreover, microwave radiation toward the plasma region is optimized by adjusting the height H and the width W of the ridge portion so that there is no microwave power reflection and the length of the line-shaped plasma 80 is extended. Generally, the height H is within a range from 0 to ¼ of the wavelength of the microwave 70. Here, the wavelength is referred to as the wavelength of the microwave 70 traveling inside the ridged wave-guide 220 instead of the wavelength of the microwave 70 traveling in free space. The width W of the line-shaped slot 226 is, for example, within a range from 0 to the width of the first wide side 222a (or the second wide side 222b) of the ridged wave-guide 220. Those with ordinary skills in the art can make modifications within the scope of the present invention.

Accordingly, in the microwave-excited plasma source of the present invention, there is less possibility for film deposition on the separation plate and less possibility for plasma etching on the separation plate. Therefore, the separation plate can be less frequently renewed to reduce the operation cost of the microwave-excited plasma source. Moreover, microwave radiation toward the plasma region is maximized by adjusting height H and the width W of the ridge portion so that there is no microwave power reflection and the length of the line-shaped plasma is extended.

According to the above discussion, it is apparent that the present invention discloses a microwave-excited plasma source and a plasma-discharging device using such a microwave-excited plasma source, the microwave-excited plasma source comprises an inner electrode having a cooling channel disposed therein for introducing a working fluid into the inner electrode as a cooling fluid to effectively reduce the electrode temperature, prevent the inner electrode from consumption, prolong the lifetime of the inner electrode and avoid contamination due to ion stripping.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A microwave-excited plasma source, comprising:
a reaction chamber;
a ridged wave-guide, disposed on the reaction chamber, the ridged wave-guide comprising:
a frame portion;
a line-shaped slot, disposed on a first side of the frame portion, the first side being adjacent to the reaction chamber;
a ridge portion, disposed on a second side of the frame portion, the ridge portion facing the line-shaped slot; and
a separation plate, disposed on the line-shaped slot.

2. The microwave-excited plasma source as recited in claim 1, wherein the reaction chamber comprises an opening, the ridged wave-guide being disposed above the opening and the line-shaped slot facing the opening.

3. The microwave-excited plasma source as recited in claim 1, wherein the separation plate is formed of quartz glass.

4. The microwave-excited plasma source as recited in claim 1, wherein the ridged wave-guide is formed of metal.

5. The microwave-excited plasma source as recited in claim 1, wherein the ridged wave-guide is capable of concentrating microwave power, which is transmitted to the reaction chamber through the line-shaped slot in order to excite plasma.

6. The microwave-excited plasma source as recited in claim 5, wherein the distance between the ridge portion and the line-shaped slot is within a range from 0 to ¼ of the wavelength of the microwave.

7. The microwave-excited plasma source as recited in claim 1, wherein the width of the line-shaped slot is within a range from 0 to the width of the first side.

8. The microwave-excited plasma source as recited in claim 1, further comprising a base and a substrate disposed inside the reaction chamber, wherein the substrate is disposed on the base and under the line-shaped slot.

9. The microwave-excited plasma source as recited in claim 8, wherein a carrier tape is disposed on the base and the substrate is disposed on the carrier tape.

10. The microwave-excited plasma source as recited in claim 1, wherein the first side is a first wide side, and the second side is a second wide side.
